(19) United States
(12) Patent Application Publication
(10) Pub. No.: US 2005/0244723 A1
(43) Pub. Date: Nov. 3, 2005

(54) Lithography mask for the fabrication of semiconductor components

(76) Inventors: Christian Holfeld, Dresden (DE); Jenspeter Rau, Muenchen (DE)

Correspondence Address: SLATER & MATSIL LLP, 17950 PRESTON ROAD, SUITE 1000, DALLAS, TX, 75252, US

(21) Appl. No.: 11/095,926

(22) Filed: Mar. 31, 2005

(30) Foreign Application Priority Data
Mar. 31, 2004 (DE) 10 2004 017 131.9

(51) Int. Cl. B32B 17/06; B32B 9/00; G21K 5/00; G03F 9/00

(52) U.S. Cl. 430/5; 378/35; 428/428

(57) ABSTRACT

The invention relates to a lithography mask for fabricating semiconductor components with at least one reflective multilayer structure on a mask substrate, a first structure being arranged in and/or on the multilayer structure, and with at least one absorber layer, characterized in that a second structure (2) is arranged in and/or on the absorber layer (20), the characteristic length of the first structure (1) is 1.5 to 10 times greater than the characteristic length of the second structure (2). This creates a lithography mask, which can be used to fabricate structures having a very different size and/or form on a substrate.

This application claims priority to German Patent Application 10 2004 017 131.9, which was filed Mar. 31, 2004 and is incorporated herein by reference.

### TECHNICAL FIELD

The invention relates to a lithography mask for fabricating semiconductor components with at least one reflective multilayer structure.

### BACKGROUND

Photolithographic masks are used in the fabrication of semiconductor components, such as, e.g., DRAM memory chips. In this case, a distinction is made between transmission and reflection masks. In the case of transmission masks, the radiation passes through the light-transmissive parts of the mask and impinges on a substrate on which a structure is intended to be produced. In the case of the reflection mask, the light is radiated back onto a substrate from reflective parts of the mask for producing a structure.

Reflection masks are used, e.g., for lithography with very short-wave light. This includes extreme ultraviolet (EUV; wavelengths approximately 0.1 to 100 nm, in particular 13.5 nm) and also X-ray radiation having even shorter wavelengths.

Reflection masks generally have a mask substrate (e.g., made of silicon, glass or ceramic) with a multilayer structure and an absorber structure.

The multilayer structure serves for reflection of the incident radiation, and the absorber layer serves for absorption. It is thus possible to produce light-dark structures on a light-sensitively coated substrate for semiconductor component fabrication.

The multilayer structure is generally composed alternately of a doubling of 30 to 50 molybdenum and silicon layers lying one above the other. By way of example, tantalum, chromium or tantalum nitride are used as the absorber material.

There are two variants in the case of reflection masks: either an absorber layer is patterned on the reflective multilayer structure or a patterned layer on the multilayer structure is used as an etching mask (hard mask) in order to etch the multilayer structure itself. The hard mask is subsequently removed.

A typical multilayer structure has 40 layers with a total thickness of approximately 280 nm. The structures to be arranged in the multilayer structure thus have a high aspect ratio, so that structures are difficult or impossible to fabricate on the mask. An absorber layer, including a buffer layer, typically has a total thickness of approximately 50 to 130 nm.

In this case, it is particularly difficult to simultaneously produce small and large structures on such a mask. In part special measures have to be implemented for fabricating particularly small structures below the actual resolution capability of the lithography radiation. By way of example, so-called scatter bars, which have significantly smaller dimensions than the larger actual structures that are intended to be produced on the wafer are provided in a targeted manner for optical proximity correction.

### SUMMARY OF THE INVENTION

The present invention is based on the object of creating a lithography mask, which can be used to fabricate structures having a very different size and form on a substrate.

This object is achieved according to a preferred embodiment of the invention by means of a lithography mask for fabricating semiconductor components with at least one reflective multilayer structure on a mask substrate, a first structure being arranged in and/or on the multilayer structure, and with at least one absorber layer, characterized in that a second structure is arranged in and/or on the absorber layer, the two structures serving for producing an exposure pattern on a substrate to be exposed.

According to the preferred embodiment of the invention, the lithography mask has at least one reflective multilayer structure on a mask substrate, a first structure being arranged in and/or on the multilayer structure. Furthermore, the lithography mask has at least one absorber layer, a second structure being arranged in and/or on the absorber layer. In this case, an absorber layer is also understood to mean a multilayer system of an absorber layer with a buffer layer.

The combination of second structures on the lithography mask makes it possible to arrange structures having a different form and/or size with the fabrication method appropriate in each case. It is thus possible to arrange structures having a similar production characteristic (similar process window) in the respectively suitable layers of the lithography mask.

This is particularly advantageous if the characteristic length (e.g., linewidth) of the first structure is 1.5 to 10 times greater than the characteristic length of the second structure. The combination of a first and a second structure in differently reflective regions of the lithography mask makes it possible, in the exposure result, to fabricate structures of semiconductor components, which have different sizes.

In this case, it is advantageous if the second structure is designed for producing an OPC structure, in particular as a scatter bar. This is an application in which structures having a different size have to be introduced into a substrate.

It is also advantageous if the first and second structures are different in terms of their form, with the result that the form of the respective layer of the lithography mask can be adapted. It is thus easier to fabricate holes (smaller aspect ratio) with the second structure in the thinner absorber layer.

In an advantageous manner, the characteristic length of the first structure is 180 nm and the characteristic length of the second structure is 100 nm.

An advantageous refinement of the lithography mask according to the invention has a mask substrate, which has silicon, glass and/or ceramic or comprises these materials.

The multilayer structure advantageously has at least 20 layers made of molybdenum and silicon lying alternately one above the other. It is also advantageous if the absorber layer has a proportion of chromium, tantalum and/or tantalum nitride or comprises these materials.

### BRIEF DESCRIPTION OF THE DRAWINGS

The invention is explained in more detail below using a plurality of exemplary embodiments with reference to the figures of the drawings, in which:

FIG. 1 shows a schematic illustration of a first embodiment of a lithography mask according to the invention;

FIG. 2 shows a schematic illustration of a second embodiment of a lithography mask according to the invention; and

FIG. 3 shows a schematic illustration of a third embodiment of a lithography mask according to the invention.

The following list of reference symbols can be used in conjunction with the figures:
1 First structure
2 Second structure
10 Multilayer structure
20 Absorber layer
100 Mask substrate

### DETAILED DESCRIPTION OF ILLUSTRATIVE EMBODIMENTS

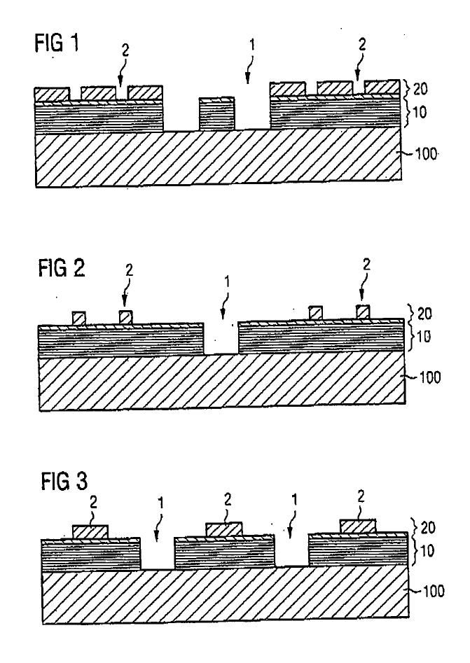

FIG. 1 illustrates, as a first embodiment of the lithography mask according to the invention, a reflection mask with a mask substrate 100 in a sectional view. The radiation from a lithography light source (in this case EUV light having a wavelength of 13.5 nm) falls onto the lithography mask from above and is used by reflective portions of the lithography mask for exposing a substrate that is not illustrated here. A structure is produced on the substrate by means of the reflected light.

The reflective portion is formed by a multilayer structure 10 on the lithography mask. This is a layer sequence of 40 alternate molybdenum and silicon layers. These layers reflect the short-wave UV light.

The regions from which no reflection is to proceed are covered with an absorber layer 20 made of chromium, tantalum or tantalum nitride. The absorber layer 20 is illustrated as uniform here for reasons of clarity. The absorber layer 20 may also contain a buffer layer that is not illustrated here.

In the case of the lithography mask in accordance with FIG. 1, a first structure 1 is introduced in the multilayer structure 10, and forms a dark structure. The absorber layer 20 is provided with a second structure 2, the characteristic length (e.g., line width, dimension of a square structure) of which is a factor of 1.5 to 10 smaller than that of the first structure 1. The second structure 2 will arise in reflection as a bright structure against a dark background.

In this case, the second structure 2 is designed as a scatter bar for an OPC, the scatter bars being associated with the first structure 1, which is significantly larger. However, the second structure 2 may also differ in form from the first structure 1.

This results in a combination of a first and a second structure 1, 2 whose size ratios and/or form ratios are different. Depending on the size and/or form ratio, it is possible to choose the suitable position on the lithography mask, i.e., absorber layer 20 or multilayer structure 10. During the fabrication of lithography masks there are specific process windows that have to be observed. Thus, by way of example, etching speed into the depth, the lateral resolution of the structures produced and the sidewall profile depend on the structure size and form. The division of the structures, i.e., the separate production on the lithography mask according to structure size and form is expedient for this reason.

In an exposure step, with these two structures 1, 2, a pattern is fabricated on a substrate to be exposed, not all the structures 1, 2 having to be printed on the substrate. If one of the structures is, e.g., an OPC structure, then the latter is not printed on the substrate.

In this case, simulations show that the process windows differ for structures of identical type in the absorber layer 20 and the multilayer structure 10. Through skillful positioning of the structures 1, 2 in the absorber layer 20 and the multilayer structure 10, it is possible to increase the overlap of the process windows (in this case the dose and defocus settings for sufficient exposure results) for the different structures 1, 2.

With regard to the characteristic lengths, the following minimum values are to be expected according to the International Roadmap of Semiconductors 2003, taking account of a 4-fold reduction from the lithography mask to the substrate (wafer):

| | |
|---|---|
| 45 nm node: | imaged structure: 180 nm |
| | smallest line (OPC); 100 nm |
| | contact hole: 200 nm |
| 32 nm node: | imaged structure: 128 nm |
| | smallest line (OPC): 72 nm |
| | contact hole: 120 nm |

FIG. 2 illustrates a second embodiment, in which the conditions are reversed in comparison with FIG. 1. In this case, the multilayer structure 10 has largely been freed of an absorber layer 20. Only the second structure 2 is formed from parts of an absorber layer 20. In this case, too, the absorber layer 20 may have a buffer layer that is not illustrated here.

Consequently, a dark structure on a bright background is produced in reflection. In this case, too, a significantly larger first structure 1 and a small second structure 2 can be imaged in parallel.

FIG. 3 illustrates a third embodiment of the lithography mask according to the invention. The vertical layer construction essentially corresponds to that described above. In the case of the third embodiment, a regular, alternating structure is created in which a dark second structure 2 is formed in the absorber layer 20. A first structure 1 is arranged, likewise in alternating fashion, in a manner offset with respect thereto.

The embodiment of the invention is not restricted to the preferred exemplary embodiments specified above. Rather, a number of variants are conceivable, which make use of the lithography mask according to the invention also in the case of embodiments of fundamentally different configuration.

1. A lithography mask for fabricating semiconductor components, the lithography mask comprising:
a mask substrate;
at least one reflective multilayer structure over the mask substrate;
a first structure arranged in and/or on the multilayer structure;
at least one absorber layer overlying the mask substrate; and
a second structure arranged in and/or on the absorber layer, the first structure and the second structure serving to produce an exposure pattern on a substrate to be exposed.

2. The lithography mask according to claim 1, wherein the first structure has a characteristic length that is 1.5 to 10 times greater than a characteristic length of the second structure.

3. The lithography mask according to claim 1, wherein the second structure comprises an OPC structure.

4. The lithography mask according to claim 1, wherein the second structure comprises a scatter bar.

5. The lithography mask according to claim 1, wherein the first structure is formed in linear fashion.

6. The lithography mask according to claim 5, wherein the second structure is formed in punctiform fashion.

7. The lithography mask according to claim 1, wherein the second structure is formed in punctiform fashion.

8. The lithography mask according to claim 1, wherein a characteristic length of the first structure is 180 nm and a characteristic length of the second structure is 100 nm.

9. The lithography mask according to claim 1, wherein the mask substrate comprises at least one material selected from the group consisting of silicon, glass and ceramic.

10. The lithography mask according to claim 1, wherein the multilayer structure includes at least 20 layers made of molybdenum and silicon lying alternately one above the other.

11. The lithography mask according to claim 1, wherein the absorber layer comprises chromium, tantalum and/or tantalum nitride.

12. A lithography mask comprising:
a mask substrate;
a reflective layer overlying the mask substrate, the reflective layer comprising a multilayer structure,
an absorber layer overlying the reflective layer;
a first plurality of openings formed throughout the reflective layer and the absorber layer; and
a second plurality of openings formed throughout the absorber layer, the second plurality of openings each including a bottom surface that overlies the reflective layer.

13. The lithography mask according to claim 12, wherein the second openings comprise OPC structures.

14. The lithography mask according to claim 13, wherein the second openings comprise scatter bars.

15. The lithography mask according to claim 12, wherein the second openings separate remaining portions of the absorber layer, the remaining portions of the absorber layer comprising OPC structures.

16. The lithography mask according to claim 12, wherein the reflective layer includes at least 20 layers made of molybdenum and silicon lying alternately one above the other.

17. The lithography mask according to claim 12, wherein the first openings each have a first characteristic length and wherein the second openings each have a second characteristic length wherein the first characteristic length is 1.5 to 10 times greater than the second characteristic length.

18. The lithography mask according to claim 17, wherein the first characteristic length is about 180 nm and the second characteristic length is about 100 nm.

19. The lithography mask according to claim 12, wherein the mask substrate comprises at least one material selected from the group consisting of silicon, glass and ceramic.

20. The lithography mask according to claim 12, wherein the absorber layer comprises chromium, tantalum and/or tantalum nitride.
